(19) United States
(12) Patent Application Publication
(10) Pub. No.: US 2009/0115045 A1
(43) Pub. Date: May 7, 2009

(54) Stacked package module and method for fabricating the same

(75) Inventors: Shih-Ping Hsu, Sinfong Township (TW); Chia-Wei Chang, Sinfong Township (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/289,647

(22) Filed: Oct. 31, 2008

(30) Foreign Application Priority Data
Nov. 2, 2007 (TW) 09614601

(51) Int. Cl. H01L 23/02

(52) U.S. Cl. 257/686; 257/E23.18

(57) ABSTRACT

The present invention relates to a stacked package module and a method for fabricating the same. The stacked package module comprises: a first package structure, a second package structure, a ceramic-surfaced aluminum plate, and a metal paste. Herein, the ceramic-surfaced aluminum plate has a plurality of through holes filled with the metal paste to correspond with and electrically connect the first conductive pads of the first package structure and the second conductive pads of the second package structure; and the ceramic-surfaced aluminum plate further has a first cavity to receive a chip. Besides, the present invention provides a stacked package module, which can avoid warpage, omit the process for soldering, favor the shrinkage of size and pitch of the conductive pads, and also can reduce the height of the package.

### BACKGROUND OF THE INVENTION

1. Field of the Invention

The present invention relates to a stacked package module and a method for fabricating the same and, more particularly, to a stacked package module and a method for fabricating the same, which can avoid warpage, omit the process for soldering, favor the shrinkage of size and pitch of the conductive pads, and also can reduce the height of the package.

2. Description of Related Art

As the electronics industry develops rapidly, research accordingly moves towards electronic devices with multifunction and high efficiency. Hence, packaging substrates with many active and passive components and circuit connections have advanced from being single-layered boards to multiple-layered boards so that the packaging requirements such as integration and miniaturization in semiconductor packaging can be met. Furthermore, interlayer connection technique is also applied in this field to expand the space for wiring layout in a limited packaging substrate and to meet the demand of the application of high-density integrated circuits. In addition, in order to meet the requirements of miniaturization and multifunction in products, the package structures with high pincounts and excellent performance have become popular. At the same time, system-in-package (SIP) has been developed to integrate various chips or electronic components into a single package module so as to achieve system function. SIP exhibits many advantages, such as miniaturization, high performance and low cost. Also, SIP can reduce or omit the demands for high speed circuits, and significantly reduce the noises from electromagnetic interference (EMI).

As shown in FIG. 1, a conventional stacked package module in system-in-package (SIP) integrates two package structures into a single package module by package on package (POP). The conventional package module includes a first package structure 1 and a second package structure 1′. The first package structure 1 and the second package structure 1′ are wire bonding package structures. The first package structure 1 mainly consists of a packaging substrate 10, a chip 11, a plurality of metal wires 14 and a molding material 15. Herein, the first surface 10a of the packaging substrate 10 has a plurality of wire bonding pads 101 and a plurality of first conductive pads 102 thereon, and the second surface 10b has a plurality of second conductive pads 103 thereon. The chip 11 is disposed on the first surface 10a of the packaging substrate 10, and the active surface 11a of the chip 11 has a plurality of electrode pads 111 thereon that electrically connect to the wire bonding pads 101 of the packaging substrate 10 through the metal wires 14. In addition, the molding material 15 encapsulates the chip 11 and the metal wires 14. Also, a plurality of solder balls 104 are disposed on the first conductive pads 102 of the first package structure 1 to stack the second package structure 1′ on the first package structure 1. Herein, the type of the second package structure 1′ is the same as that of the first package structure 1.

However, the aforementioned stacked package module has several drawbacks: first, warpage will occur in the stacked package module due to its unsymmetrical structure; second, when two package structures electrically connect to each other through solder balls, the incomplete coating of booster flux on soldering connections will result in cold join; and third, in the case that the second package structure is stacked above the first package structure, the molding material and the chip restrict the minimum gap between the first and second package structures, so that it is difficult to reduce the height of the package module and the minimum sizes of the solder balls and the conductive pads are also limited. Thereby, the conventional stacked package module cannot significantly reduce the usage of solder materials and the pitch of the conductive pads, and thereby cannot meet the requirement of miniaturization in products.

Accordingly, the purpose of the present invention is to provide a stacked package module that can improve the aforementioned drawbacks.

### SUMMARY OF THE INVENTION

The object of the present invention is to provide a stacked package module, which can avoid warpage. In addition, the present invention can omit the process for soldering so as to inhibit that the incomplete coating of booster flux on soldering connections results in cold join when two package structures electrically connect to each other by solder balls. Furthermore, the present invention favors shrinkage of pitch of the conductive pads, and can reduce cost. Also, the present invention can reduce the height of the package module to meet the requirement of miniaturization of products.

To achieve the above object, the present invention provides a stacked package module, comprising: a first package structure, comprising a first chip and a first packaging substrate, wherein the first chip electrically connects to the first packaging substrate, which has a first surface with a plurality of first conductive pads thereon and an opposite second surface with a plurality of second conductive pads thereon; a second package structure, comprising a second chip and a second packaging substrate, wherein the second chip electrically connects to the second packaging substrate, which has a first surface and an opposite second surface with a plurality of second conductive pads thereon; a ceramic-surfaced aluminum plate, disposed between the first package structure and the second package structure, wherein the first chip is disposed on the first surface of the first packaging substrate, the ceramic-surfaced aluminum plate has a first cavity to receive the first chip therein and a plurality of through holes of which two opposite ends respectively correspond to the first conductive pads of the first package structure and the second conductive pads of the second package structure; and a metal paste, with which the through holes of the ceramic-surfaced aluminum plate is filled to electrically connect the first conductive pads of the first package structure and the second conductive pads of the second package structure.

In the stacked package module of the present invention, the first and second package structures can be any type of package structure, such as flip chip package structure, wire bonding package structure and so on. Herein, if the first package structure is a package structure where the first chip is disposed on the first surface of the first packaging substrate, such as a flip chip package structure or a wire bonding package structure, the ceramic-surfaced aluminum plate can further have a first cavity to receive the first chip. Similarly, if the second package structure is a package structure where the second chip is disposed on the second surface of the second packaging substrate, such as a flip chip package structure or a wire bonding package structure, the ceramic-surfaced aluminum plate can further have a second cavity to receive the second chip. In addition, the type of the first package structure can be the same as or different from that of the second package structure.

In the stacked package module of the present invention, if the first surface of the first packaging substrate further has at least one first passive component thereon, the ceramic-surfaced aluminum plate can further have at least one third cavity to receive the first passive component therein. Similarly, if the second surface of the second packaging substrate further has at least one second passive component thereon, the ceramic-surfaced aluminum plate can further have at least one fourth cavity to receive the second passive component therein.

In the stacked package module of the present invention, the material of the metal paste is not limited. Preferably, the metal paste is copper paste or silver paste.

The present invention further provides a method for fabricating a stacked package module, comprising: providing a ceramic-surfaced aluminum plate, having a first cavity and a plurality of through holes; filling the through holes with a metal paste; and placing a first package structure and a second package structure on two opposite surfaces of the ceramic-surfaced aluminum plate to allow the metal paste to electrically connect the first package structure and the second package structure, wherein the first package structure comprises a first chip and a first packaging substrate, in which the first chip electrically connects to the first packaging substrate and is received in the first cavity of the ceramic-surfaced aluminum plate, and the first packaging substrate has a first surface with a plurality of first conductive pads thereon and an opposite second surface with a plurality of second conductive pads thereon, the second package structure comprises a second chip and a second packaging substrate, in which the second chip electrically connects to the second packaging substrate and has a first surface and an opposite second surface with a plurality of second conductive pads thereon, and two opposite ends of the through holes of the ceramic-surfaced aluminum plate respectively correspond to the first conductive pads of the first package structure and the second conductive pads of the second package structure to allow the second conductive pads of the second package structure to electrically connect to the first conductive pads of the first package structure through the metal paste.

In the method for fabricating a stacked package module according to the present invention, the order for placing the first and second package structures is not limited. Herein, the first package structure can be first placed on one surface of the ceramic-surfaced aluminum plate, and then the second package structure is placed on another opposite surface of the ceramic-surfaced aluminum plate. Alternatively, the second package structure is first placed on one surface of the ceramic-surfaced aluminum plate, and then the first package structure is placed on another opposite surface of the ceramic-surfaced aluminum plate.

In the method for fabricating a stacked package module according to the present invention, the through holes can be filled with the metal paste by any method. Preferably, the through holes are filled with the metal paste by printing or dispensing.

Accordingly, the present invention can avoid warpage due to the utilization of the ceramic-surfaced aluminum plate with high rigidity. In addition, since the ceramic-surfaced aluminum plate has a plurality of through holes for being filled with the metal paste to electrically connect two package structures, the process for soldering can be omitted so as to inhibit that the incomplete coating of booster flux on soldering connections results in cold join when two package structures electrically connect to each other by solder balls. Also, it can be inhibited that the usage of solder balls to electrically connect two package structures results in the minimum size limit of solder balls and conductive pads. Accordingly, the present invention favors the shrinkage of size and pitch of the conductive pads and can reduce the usage of the metal paste to save cost. Besides, the ceramic-surfaced aluminum plate used in the present invention further has a cavity to receive a chip or a passive component, so as to reduce the height of the package module and thereby meet the requirement of miniaturization of products.

Other objects, advantages, and novel features of the invention will become more apparent from the following detailed description when taken in conjunction with the accompanying drawings.

### BRIEF DESCRIPTION OF THE DRAWINGS

FIG. 1 shows a cross-sectional view of a conventional stacked package module;

FIGS. 2A to 2C′ show cross-sectional views for illustrating a process of fabricating a stacked package module according to a preferred embodiment of the present invention; and

FIGS. 3A to 3C′ show cross-sectional views of stacked package modules according to other preferred embodiments of the present invention.

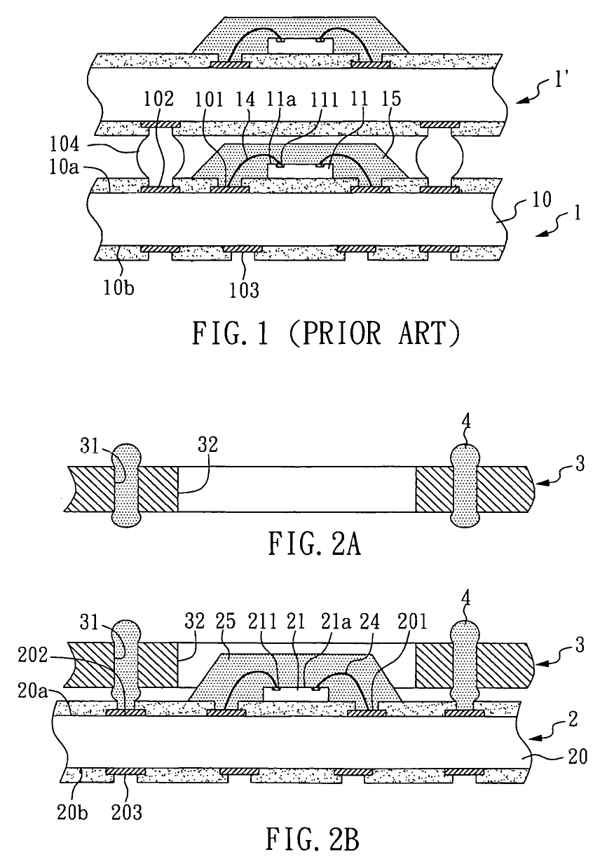

### DETAILED DESCRIPTION OF THE PREFERRED EMBODIMENT

Because the specific embodiments illustrate the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### Embodiment 1

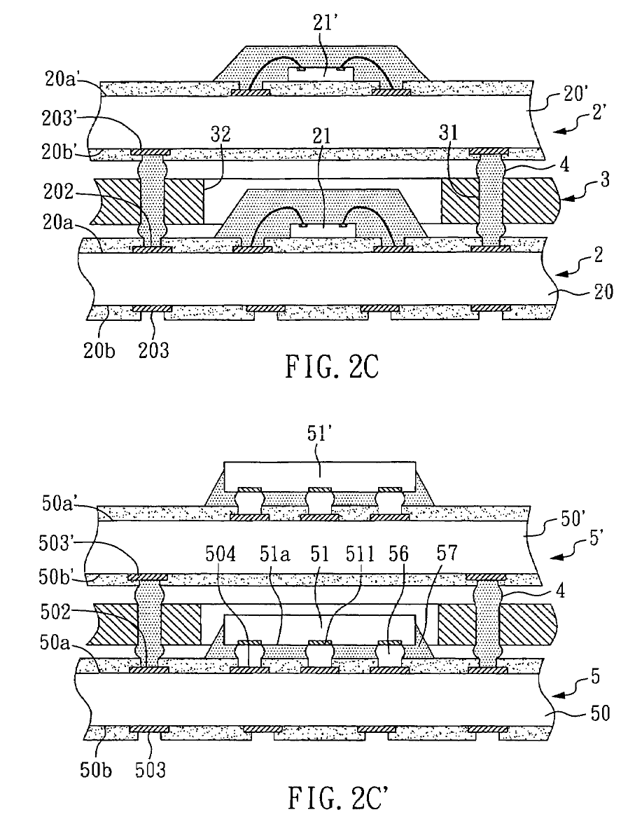

With reference to FIGS. 2A to 2C, there are shown cross-sectional views for illustrating a method for fabricating a stacked package module according to a preferred embodiment of the present invention.

As shown in FIG. 2A, a ceramic-surfaced aluminum plate 3 is first provided, which has a plurality of through holes 31 and a first cavity 32. Then, the through holes 31 are filled with a metal paste 4. Herein, the through holes 31 can be filled with the metal paste 4 by printing or dispensing and the material of the metal paste 4 is not limited. In the present embodiment, the metal paste 4 is copper paste with which the through holes 31 are filled by dispensing.

Subsequently, as shown in FIG. 2B, a first package structure 2 is placed on one surface of the ceramic-surfaced aluminum plate 3. Herein, the first package structure 2 includes a first chip 21 and a first packaging substrate 20. The first chip 21 electrically connects to the first packaging substrate 20 that has a first surface 20a and an opposite second surface 20b. The first surface 20a has a plurality of first conductive pads 202 thereon, and the second surface 20b has a plurality of second conductive pads 203 thereon. In detail, the first package structure 2 mainly consists of a first packaging substrate 20, a first chip 21, a plurality of metal wires 24 and a molding material 25. The first chip 21 is disposed on the first surface 20a of the first packaging substrate 20, and the active surface 21a of the first chip 21 has a plurality of electrode pads 211 thereon. The electrode pads 211 electrically connect to the wire bonding pads 201 of the first packaging substrate 20 through the metal wires 24. In addition, the molding material 25 encapsulates the first chip 21 and the metal wires 24. As shown in FIG. 2B, the through holes 31 correspond to the first conductive pads 202 of the first package structure 2, and the metal paste 4 electrically connects to the first conductive pads 202 of the first package structure 2. Herein, the first cavity 32 is used to receive the first chip 21.

Finally, as shown in FIG. 2C, a second package structure 2′ is placed on another opposite surface of the ceramic-surfaced aluminum plate 3. Herein, the type of the second package structure 2′ is the same as that of the first package structure 2. The second package structure 2′ includes a second chip 21′ and a second package substrate 20′. The second chip 21′ electrically connects to the second packaging substrate 20′ that has a first surface 20a′ and an opposite second surface 20b′. The second surface 20b′ has a plurality of second conductive pads 203′ thereon. The second conductive pads 203′ of the second package structure 2′ electrically connect to the metal paste 4, so that the second conductive pads 203′ of the second package structure 2′ electrically connect to the first conductive pads 202 of the first package structure 2 through the metal paste 4.

Accordingly, the present embodiment provides a stacked package module, as shown in FIG. 2C, including: a first package structure 2 including a first chip 21 and a first packaging substrate 20, wherein the first chip 21 electrically connects to the first packaging substrate 20, which has a first surface 20a with a plurality of first conductive pads 202 thereon and an opposite second surface 20b with a plurality of second conductive pads 203 thereon; a second package structure 2′ including a second chip 21′ and a second packaging substrate 20′, wherein the second chip 21′ electrically connects to the second packaging substrate 20′, which has a first surface 20a′ and an opposite second surface 20b′ with a plurality of second conductive pads 203′ thereon; a ceramic-surfaced aluminum plate 3 disposed between the first package structure 2 and the second package structure 2′, wherein the ceramic-surfaced aluminum plate 3 has a first cavity 32 to receive the first chip 21 therein and a plurality of through holes 31 of which two opposite ends respectively correspond to the first conductive pads 202 of the first package structure 2 and the second conductive pads 203′ of the second package structure 2′; and a metal paste 4, with which the through holes 31 of the ceramic-surfaced aluminum plate 3 is filled to electrically connect the first conductive pads 202 of the first package structure 2 and the second conductive pads 203′ of the second package structure 2′.

Also, the present embodiment provides another stacked package module as shown in FIG. 2C′. The structure illustrated in FIG. 2C′ is the same as that of FIG. 2C, except that the first package structure 5 and the second package structure 5′ are flip chip package structures.

### Embodiment 2

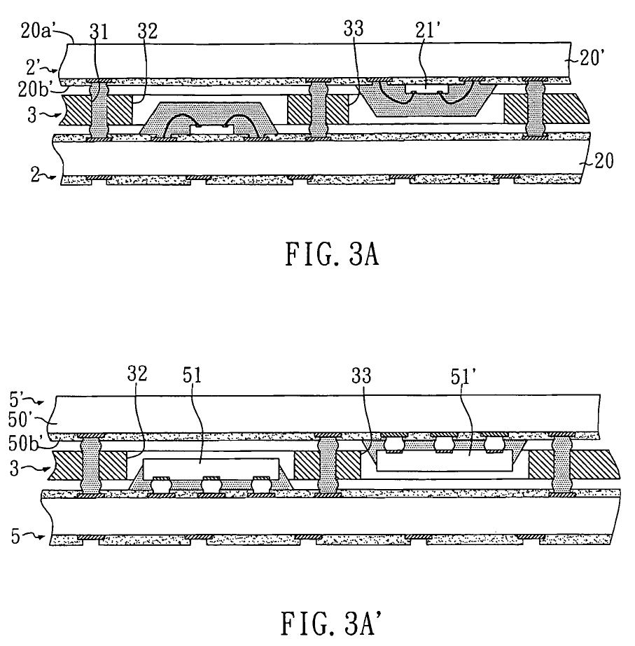

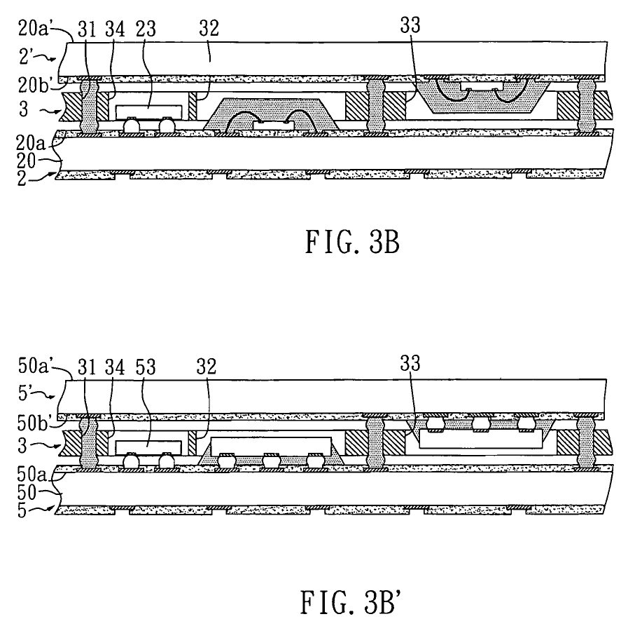

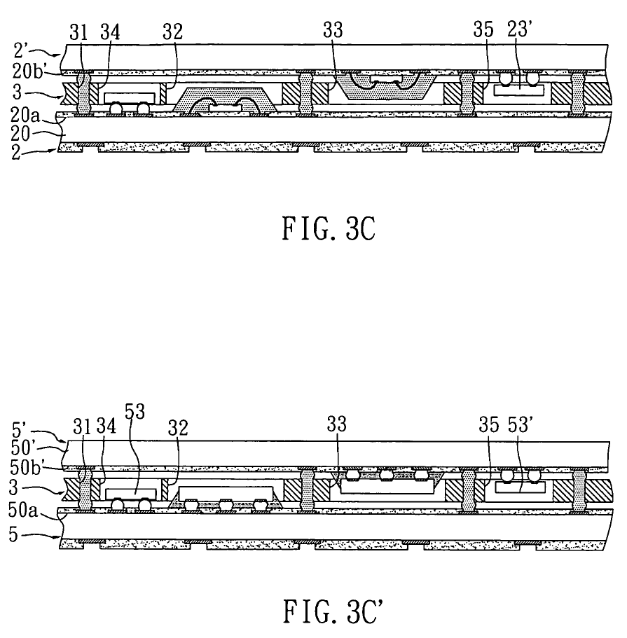

The present embodiment is the same as Embodiment 1, except that in the present embodiment the second chip 21′ is disposed on the second surface 20b′ of the second packaging substrate 20′, and the ceramic-surfaced aluminum plate 3 further has a second cavity 33 to receive the second chip 21′ as shown in FIG. 3A.

Also, the present embodiment provides another stacked package module as shown in FIG. 3A′. The structure illustrated in FIG. 3A′ is the same as that of FIG. 3A, except that the first package structure 5 and the second package structure 5′ are flip chip package structures.

### Embodiment 3

The present embodiment is the same as Embodiment 2, except that at least one first passive component 23 is disposed on the first surface 20a of the first packaging substrate 20 in the present embodiment, and the ceramic-surfaced aluminum plate 3 further has at least one third cavity 34 to receive the first passive component 23, as shown in FIG. 3B.

Also, the present embodiment provides another stacked package module as shown in FIG. 3B′. The structure illustrated in FIG. 3B′ is the same as that of FIG. 3B, except that the first package structure 5 and the second package structure 5′ are flip chip package structures.

### Embodiment 4

The present embodiment is the same as Embodiment 3, except that at least one second passive component 23′ is disposed on the second surface 20b′ of the second packaging substrate 20′ in the present embodiment, and the ceramic-surfaced aluminum plate 3 further has at least one fourth cavity 35 to receive the second passive component 23′, as shown in FIG. 3C.

Also, the present embodiment provides another stacked package module as shown in FIG. 3C′. The structure illustrated in FIG. 3C′ is the same as that of FIG. 3C, except that the first package structure 5 and the second package structure 5′ are flip chip package structures.

Although the present invention has been explained in relation to its preferred embodiment, it is to be understood that many other possible modifications and variations can be made without departing from the spirit and scope of the invention as hereinafter claimed.

What is claimed is:

1. A stacked package module, comprising:
a first package structure, comprising a first chip and a first packaging substrate, wherein the first chip electrically connects to the first packaging substrate, which has a first surface with a plurality of first conductive pads thereon and an opposite second surface with a plurality of second conductive pads thereon;
a second package structure, comprising a second chip and a second packaging substrate, wherein the second chip electrically connects to the second packaging substrate, which has a first surface and an opposite second surface with a plurality of second conductive pads thereon;
a ceramic-surfaced aluminum plate, disposed between the first package structure and the second package structure, wherein the first chip is disposed on the first surface of the first packaging substrate, the ceramic-surfaced aluminum plate has a first cavity to receive the first chip therein and a plurality of through holes of which two opposite ends respectively correspond to the first conductive pads of the first package structure and the second conductive pads of the second package structure; and
a metal paste, with which the through holes of the ceramic-surfaced aluminum plate is filled to electrically connect the first conductive pads of the first package structure and the second conductive pads of the second package structure.

2. The stacked package module as claimed in claim 1, wherein the second chip is disposed on the second surface of the second packaging substrate and the ceramic-surfaced aluminum plate further has a second cavity to receive the second chip therein.

3. The stacked package module as claimed in claim 1, wherein the first surface of the first packaging substrate further has at least one first passive component thereon, and the ceramic-surfaced aluminum plate further has at least one third cavity to receive the first passive component.

4. The stacked package module as claimed in claim 3, wherein the second surface of the second packaging substrate further has at least one second passive component thereon, and the ceramic-surfaced aluminum plate further has at least one fourth cavity to receive the second passive component.

5. The stacked package module as claimed in claim 1, wherein the metal paste is copper paste or silver paste.
